(19) United States
(12) Patent Application Publication
(10) Pub. No.: US 2015/0264811 A1
(43) Pub. Date: Sep. 17, 2015

(54) FLEXIBLE PRINTED CIRCUIT BOARD

(71) Applicant: MINEBEA CO., LTD., Kitasaku-gun (JP)

(72) Inventor: Dohaku INAMORI, SAKU-CITY (JP)

(21) Appl. No.: 14/639,389

(22) Filed: Mar. 5, 2015

(30) Foreign Application Priority Data
Mar. 14, 2014 (JP) 2014-052109

(51) Int. Cl. H05K 1/11

(52) U.S. Cl. CPC H05K 1/115; H05K 2201/05; H05K 2201/09545

(57) ABSTRACT

There is provided a flexible printed circuit board that is provided with: an insulating layer having flexibility; at least one electrode including: an upper surface electrode formed on an upper surface of the insulating layer; a lower surface electrode S formed on a lower surface of the insulating layer; and a through hole that penetrates the insulating layer and electrically connects the upper surface electrode and the lower surface electrode; and a protrusion formed at a position near the through hole.

### BACKGROUND OF THE INVENTION

1. Field of the Invention The present invention relates to a flexible printed circuit board suitable to transmit an electrical signal in limited space.

2. Description of the Related Art

For example, a strain measuring device for measuring strain of a structural object has a flexible printed circuit board (FPC board) having a very thin strain gauge and also, a flexible printed circuit board having the so-called comb-shaped electrode with plural electrodes projected in parallel is soldered and bonded to an electrode of the FPC board in order to take an output from the strain gauge.

Also, in the case of electrical equipment, such as a video camera or a digital camera having an autofocus function, internally having an actuator driven by electrical signals of electrical components or electronic components mounted at a high density, a flexible printed circuit board for making connection between the electronic components or the electrical components mounted in the actuator and electronic components or electrical components mounted in a stationary part of an equipment body is cabled from the standpoint of reduction in size and weight.

As described above, such a flexible printed circuit board generally has a structure in which the so-called comb-shaped electrode with plural thin elongated electrodes projected from the flexible printed circuit board is soldered and bonded to an electrode of the other side. Such a structure is not limited to the electrical equipment as described above, and is common in other general electrical equipment.

FIGS. 6A-6C are lateral sectional diagrams showing a process in which a comb-shaped electrode of the conventional flexible printed circuit board 5 described above is conductively connected to an electrode 90 of the other side of a printed circuit board (PCB) by solder. Hereinafter, each elongated electrode configuring this comb-shaped electrode 50 is simply called an “electrode 500”.

Each conventional electrode 500 is formed by covering all of upper and lower surfaces of an elongated polyimide layer 510 with rolled copper foils 511, 512 and also applying plated copper foils 521, 522 respectively formed on the rolled copper foils 511, 512 and also applying plated copper foil 523 to the whole inner peripheral surface of a penetrating hole 551 for a through hole as shown in FIG. 6A.

After preliminary solder S1 (see FIG. 6B) is applied to each electrode 500 of such a comb-shaped electrode, the preliminary solder 81 is melted and bonded to the electrode 90 of the other side of the flexible printed circuit board or the printed circuit board shown in FIG. 6C. In the case of this bonding, a solder bond part 85 is formed by thermal pressurization using a heater H for thermal pressurization shown in FIG. 6C.

In the case of using a normal pulse heater H in this bonding step, as shown in FIGS. 6B and 6C, the so-called void V made of a microscopic air inside the solder is crushed, and a region X in which a lower surface electrode (plated copper foil 522 of the lower side) of the electrode 500 cannot be bonded to the electrode 90 of the other side by the solder widely occurs inside the solder bond part S5 to decrease strength of bonding between the comb-shaped electrode 50 of the flexible printed circuit board 5 and the corresponding electrode 90 of the other side. Such a decrease in the strength of bonding is undesirable in the case of using electrical equipment in which the flexible printed circuit board 5 is mounted for a long period of time.

In order to solve the problem described above, it is considered to apply a technique disclosed in, for example, JP-A-2013-168460. In this technique, solid solder is provided between core wires of coaxial cables mutually arranged in parallel and electrode pads of a conduction pattern of a printed board to connect the core wires, and this solid solder is heated by a heater tip to thereby make electrical connection between both of the core wires and the electrode pads.

Since an axis wire of the coaxial cable targeted for bonding in JP-A-2013-168460 has a certain extent of thickness, the solid solder also has the size corresponding to the thickness. As a result, the axis wire of the coaxial cable can be soldered to the electrode pad of the printed board by only controlling the amount of displacement of the press of the heater tip on a solder bond part to the extent disclosed in JP-A-2013-168460.

However, in the case of the electrode 500 of the flexible printed circuit board 5, the thickness is considerably thinner than a diameter of the axis wire of the coaxial cable disclosed in JP-A-2013-168460, with the result that solder heating and pressurization by the heater tip having accuracy of displacement as described in JP-A-2013-168460 cannot form the solder bond part with accurate dimensions.

In other words, when a connection technique for preventing an object (a cable core wire in JP-A-2013-168460) from crushing by controlling a contact height of the heater tip (pulse heater) as described in, for example, JP-A-2013-168460, that is, a technique for performing displacement control of the heater tip is simply used for the invention in the case of preventing a decrease in strength of the solder bond part, the comb-shaped electrode of the flexible printed circuit board much smaller than the cable core wire in dimensions must be soldered and bonded to the electrode of the other side, with the result that the following problems arise in the case of simultaneously soldering plural teeth of the comb.

Also as a first problem, in the case of controlling a solder thickness of a lower surface to 10 μm or less, it becomes difficult to perform displacement control of a solder heating pressurization apparatus.

Also, as a second problem, in the case of using the solder heating pressurization apparatus, preliminary solder is also applied to upper surfaces of the comb teeth, and the preliminary solder of the lower surface may be thin, and a solder layer with a uniform thickness cannot be formed between the comb teeth and the electrodes of the other side.

### SUMMARY OF THE INVENTION

The present invention has been made in view of the above circumstances, and one of objects of the present invention is to provide a flexible printed circuit board. having a structure of increasing solder bonding strength in the case of soldering an electrode of the flexible printed circuit board to an electrode of the other side by thermal pressurization.

According to an illustrative embodiment of the present invention, there is provided a flexible printed circuit board that is provided with: an insulating layer having flexibility; at least one electrode including: an upper surface electrode formed on an upper surface of the insulating layer; a lower surface electrode formed on a lower surface of the insulating layer; and a through hole that penetrates the insulating layer and electrically connects the upper surface electrode and the lower surface electrode; and a protrusion formed at a position near the through hole.

### BRIEF DESCRIPTION OF THE DRAWINGS

In the accompanying drawings:

FIG. 1 is a top view of a flexible printed circuit board according to an embodiment of the invention and a comb-shaped electrode provided in the flexible printed circuit board;

FIG. 2 is a bottom view of the flexible printed circuit board shown in FIG. 1 and the comb-shaped electrode provided in the flexible printed circuit board;

FIGS. 3A-3C are lateral sectional explanatory diagrams showing a process in which each electrode configuring the eolith-shaped electrode of the flexible printed circuit board shown in FIG. 1 is conductively connected to an electrode of the other side by solder bonding;

FIGS. 4A and 411 are views which show a first modified example of the embodiment of the invention and correspond to FIGS. 1 and 2;

FIGS. 5A and 5B are views which show a second modified example of the embodiment of the invention and correspond to FIGS. 1 and 2; and

FIGS. 6A-6C are lateral sectional explanatory diagrams showing a process in which each electrode configuring a comb-shaped electrode of a conventional flexible printed circuit board is conductively connected to an electrode of the other side by solder bonding.

### DETAILED DESCRIPTION

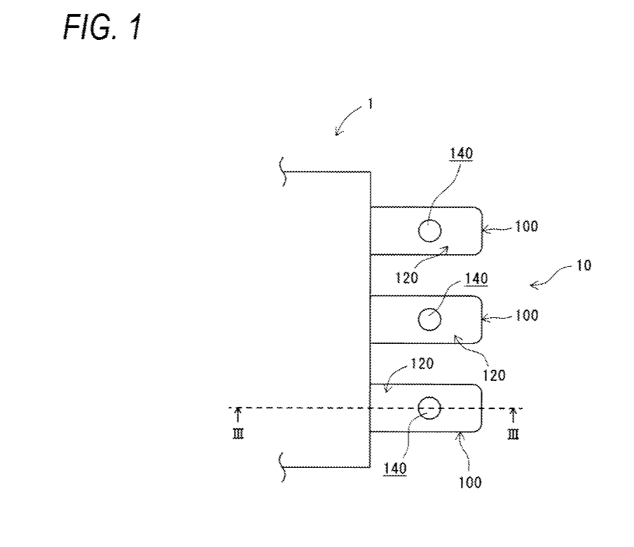

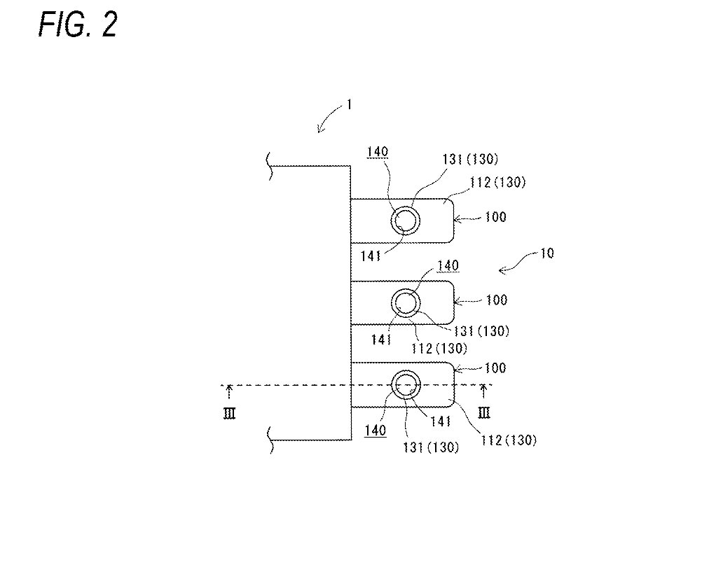

A flexible printed circuit board 1 according to an embodiment of the invention will hereinafter be described based on the drawings. FIG. 1 is a top view of the flexible printed circuit board 1 according to the embodiment of the invention and a comb-shaped electrode 10 provided in the flexible printed circuit board 1. FIG. 2 is a bottom view of the flexible printed circuit board 1 shown in FIG. 1 and the comb-shaped electrode 10 provided in the flexible printed circuit board 1. In the accompanying drawings, size, thickness and dimensions of each component are Shown to be larger than they actually are for the sake of better understanding of the structure.

The flexible printed circuit board 1 according to the embodiment has the comb-shaped electrode 10 provided with plural (three in the embodiment) elongated electrodes 100 extending outward from a side edge of the flexible printed circuit board 1 to have a overall shape like a comb.

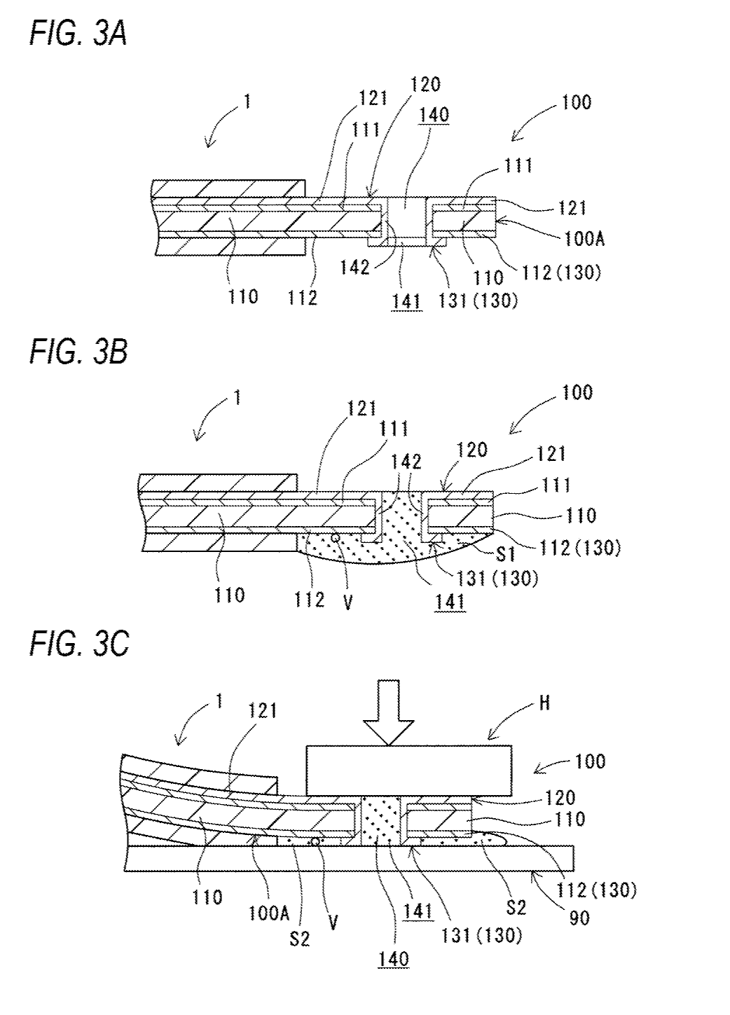

FIG. 3A is a sectional view taken on line III-III shown in FIGS. 1 and 2. Each of the electrodes 100 includes a polyimide layer 110 Which is an insulating layer, an upper surface electrode 120 and a lower surface electrode 130 respectively formed on S rolled copper foils 111, 112 covering upper and lower surfaces of this polyimide layer 110 as shown in FIG. 3A. The upper surface electrode 120 is electrically connected to the lower surface electrode 130 through a through hole 140 formed in the vicinity of the end of the electrode 100.

The comb-shaped electrode 10 provided in the flexible printed circuit board 1 is configured as described below. The comb-shaped electrode 10 of the flexible printed circuit board 1 according to the embodiment is configured based on a base material 100A. The base material 100A is provided with the polyimide layer 110 forming the insulating layer, and the rolled copper foils 111, 112 formed on all of both surfaces (upper and lower surfaces) of this polyimide layer 110. In the flexible printed circuit board 1, for example, by etching the base material 100A, a desired conductor pattern is formed on the upper and lower surfaces of the polyimide layer 110 and also, a penetrating hole for a through hole is formed in a predetermined position on the conductor pattern. In addition, the through hole 140 shown in FIG. 3A is a through hole that serves as a part of the electrode 100. That is, the through hole 140 that serves as a part of the electrode 100 is formed in a position corresponding to each of the lower surface electrodes 130 forming the comb-shaped electrode 10 according to the embodiment.

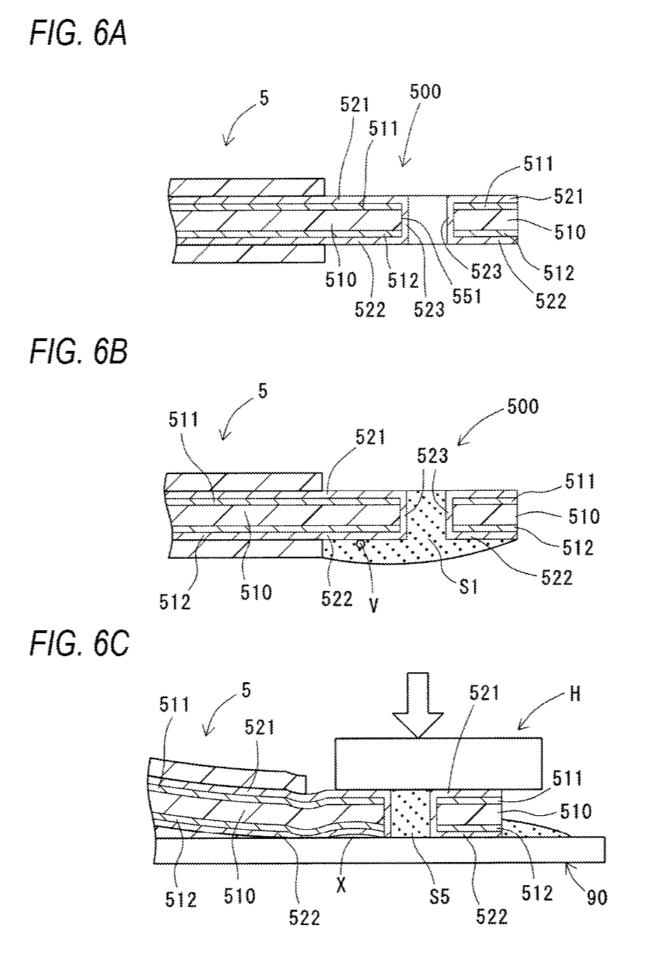

Plated copper foils 121, 131 are formed on the rolled copper foils 111, 112. The whole upper surface of the rolled copper foils 111, 112 is plated. On the other hand, the plated copper foil is applied to the lower surface so as to form an annular shape on only the periphery of a lower side opening 141 of the through hole 140. A thickness of the plated copper foil forming the annular shape (doughnut shape) is about 10 μm, which is considerably thicker than that of the conventional example shown in FIGS. 6A-6C, and this portion is configured as a protrusion 131 formed on the periphery of the through hole 140. In addition, plated copper foil 142 is applied to the inside of the through hole, and the plated copper foil 121 of the upper surface is conductively connected to the plated copper foil 131 of the lower surface. Further, a cover resist is applied to a desired region.

In the embodiment, the upper surface electrode 120 includes the plated copper foil 121, and the lower surface electrode 130 includes the rolled copper foil 112 and the protrusion 131 made of the annular plated copper foil.

In addition, since the thickness of the protrusion 131 forming a part of the lower surface electrode 130 is 10 μm, which is considerably thicker than that of the conventional example as described above. This portion serves as an electrode, and further forms a spacer functioning as a stopper for limiting movement of a pulse heater H at the time of heating and pressurizing solder by the pulse heater H.

Subsequently, as shown in FIG. 3B, preliminary solder S1 is applied to only the lower surface, and punching is performed in a comb shape using a pressing machine, and plural elongated electrodes 100 are arranged in parallel and the comb-shaped electrode 10 is formed to complete the flexible printed circuit board 1. Since the preliminary solder S1 is applied to the whole lower surface and punching is performed by the pressing machine, the amount of preliminary solder of the comb-shaped electrode 10 becomes about the same.

A procedure for soldering the comb-shaped electrode 10 of the flexible printed circuit board 1 according to the embodiment to an electrode 90 of the other side of a printed circuit board will hereinafter be described. First, the flexible printed circuit board 1 having the comb-shaped electrode 10 according to the embodiment is prepared. In addition, the flexible printed circuit board 1 to which the preliminary solder S1 is applied as shown in FIG. 6B rather than a state shown in FIG. 6A is prepared actually.

Next, the electrode 100 of the flexible printed circuit board 1 of the embodiment is soldered and bonded to the electrode 90 of the other side. The electrode 100 is soldered and bonded to the electrode 90 of the other side as shown in FIG. 3C using a general heating pressurization apparatus for pressing the pulse heater H on the normal comb-shaped electrode 10 at a constant pressure and melting the preliminary solder S1.

In the case of the embodiment, since the protrusion 131 of the lower surface electrode 130 has a form of the spacer and functions as the stopper in the case of downwardly moving the pulse heater H, a bond solder layer S2 with a uniform thickness can accurately be formed between the electrode 100 of the flexible printed circuit board 1 and the electrode 90 of the other side when the electrode 100 of the flexible printed circuit board 1 is soldered and bonded to a metal electrode made of the electrode 90 of the other side by thermal pressurization using the pulse heater H. Accordingly, even when a void V occurs in the bond solder layer S2 of the inside of a solder bond part, the S pulse heater H does not crush the void V between the electrode of the flexible printed circuit board and the electrode of the other side to which the electrode of the flexible printed circuit board is bonded, with the result that the strength of the solder bond part S2 is improved. As a result, the mechanical strength of the solder bond part between the electrodes is increased and sufficient conduction characteristics are maintained over a long period of time.

Also, since the protrusion 131 of the lower surface electrode 130 functions as the stopper of movement of the pulse heater H as described above, it becomes unnecessary to exactly perform displacement control of a solder thermal pressurization apparatus so as to change to a good solder melt state in the solder bond part S2. As a result, the electrode 100 of the flexible printed circuit board 1 according to the invention can be soldered and bonded to the electrode 90 of the other side by the normal thermal pressurization apparatus. That is, it is unnecessary to use an expensive heating pressurization apparatus capable of being applied to the present technical field which requires displacement control with accuracy higher than that of a heating pressurization apparatus for performing displacement control described in the document, JP-A-2013-168460.

Also, when the flexible printed circuit board 1 has the so-called comb-shaped electrode 10 in which the plural electrodes 100 are arranged in a comb shape, regardless of variations in solder thickness of the preliminary solder S1, a solder layer with a constant thickness can be formed between each of the electrodes 100 of the comb-shaped electrode 10 and the electrode 90 of the other side respectively soldered and bonded to the electrode 100.

Also, when the flexible printed circuit board 1 has the comb-shaped electrode 10 described above, the bond solder layer 82 with a constant thickness can similarly be formed between each of the electrodes 100 and the electrode 90 of the other side by simultaneously heating and pressurizing the comb-shaped electrode 10 by one pulse heater H even when thicknesses of the electrodes 100 configuring the comb-shaped electrode 10 differ mutually.

One example of dimensions of the comb-shaped electrode 10 of the flexible printed circuit board 1 of each component for suitably exerting action of the invention described above is shown below. When each of the electrodes 100 forming the comb-shaped electrode 10 is, for example, 0.5 mm in width and 0.7 mm in length, the annular lower surface electrode 130 formed on the peripheral edge of the lower side opening of the through hole 140 has the dimensions of 0.16 mm in an inside diameter, about 0.3 mm in an outside diameter and about 10 mm in thickness as described above.

Also, in the case of assuming that a void V is provided inside solder and this void V is present in the portion of contact between the plated copper foil 112 of the lower surface electrode 130 and the electrode of the other side, when the plated copper foil 112 is generally 0.5 mm in width and 0.7 mm in length and the annular shape is 0.3 mm in an outside diameter and 0.16 mm in an inside diameter, as compared with the conventional case of plating the whole lower surface, the lower surface electrode 130 is smaller than ever before and is about ⅙, and the possibility of a decrease in the whole bonding strength can he decreased to ⅙ even when the void V is included, and the bond solder layer S2 with a constant thickness is also formed between the comb-shaped electrode 10 and the electrode 90 of the other side, with the result that solder bonding with high reliability can be obtained.

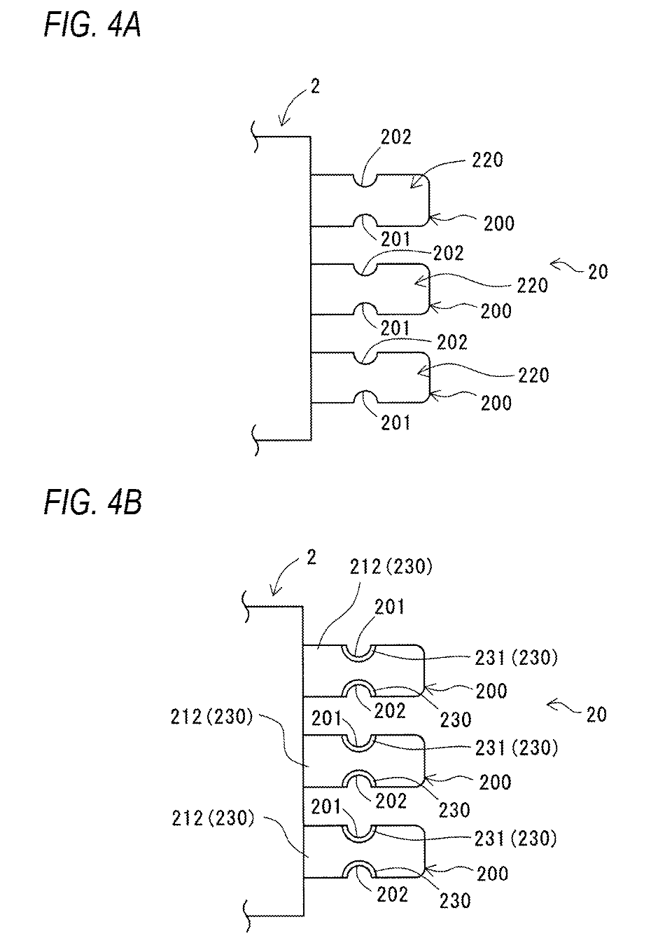

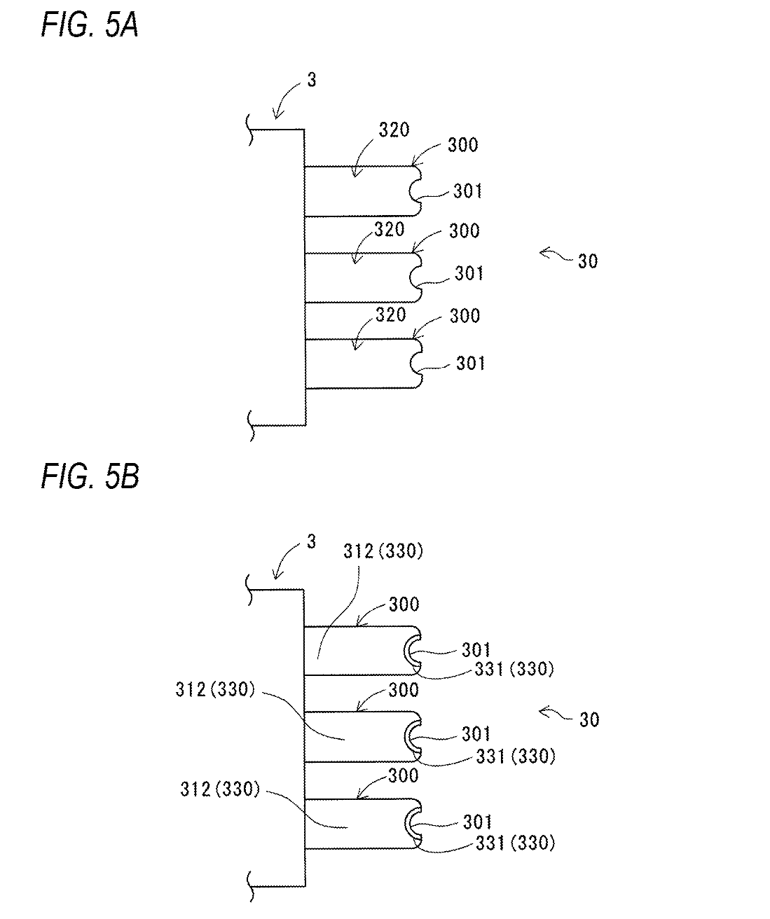

Subsequently, various modified examples of the embodiment described above will be described. FIGS. 4A and 4B are views which show a first modified example of the embodiment. FIGS. 4A and 4B show portions corresponding to those shown in FIGS. 1 and 2. FIGS. 5A and 5B are views which show a second modified example of one embodiment of the invention. FIGS. 5A and SB show portions corresponding to those shown in FIGS. 1 and 2. In addition, in both the modified examples, the detailed description is omitted by assigning the corresponding numerals to configurations equivalent to those of the embodiment described above.

A flexible printed circuit board 2 according to the first modified example of the embodiment described above will be described. In the flexible printed circuit board 2 according to the first modified example, unlike the embodiment described above, notches 201, 202 having a semicircular shape in plan view are formed in the range from an upper surface to a lower surface of an electrode 200 in predetermined positions of both side edge parts of each of the electrodes 200 forming a comb-shaped electrode 20. And, plated copper foil is applied to the whole upper surface of the electrode 200 and inner peripheral surfaces of the notches 201, 202 having the semicircular shape in plan view respectively formed in both side edge parts of the electrode 200. Also, a protrusion 231 with a thickness of about 10 mm is formed on the lower surface of the electrode 200 and the periphery of a lower side opening edge of the notch.

In the present modified example, a lower surface electrode 230 includes rolled copper foil 212 formed in a thickness similar to that of the embodiment described above, and the semicircular annular protrusion 231 made of plated copper foil similar to the embodiment described above.

Since the protrusion 231 of this lower surface electrode 230 also has a sufficient thickness like the embodiment described above, the protrusion 231 functions as a stopper in the case of displacing a pulse heater H when the pulse heater H is heated. and also a solder bond part is pressurized, and there is no fear that a void V of the inside of the solder bond part enlarges to cause insufficient bonding between an electrode 90 of the other side and the electrode 200 by solder.

Subsequently, a flexible printed circuit board 3 according to the second modified example of the embodiment described above will be described. In the flexible printed circuit board 3 according to the second modified example, unlike the embodiment described above, a notch 301 with a semicircular shape in plan view is formed in the range from an upper surface to a lower surface of an electrode 300 in a predetermined position of a distal end edge part of each of the electrodes 300 forming a comb-shaped electrode 30. And, plated copper foil is applied to the whole upper surface of each of the electrodes 300 and an inner peripheral surface of the notch 301 formed in each of the electrodes 300. Also, a semicircular annular protrusion 331 with a thickness of about 10 mm is formed on the lower surface of the electrode 300 and the periphery of a lower side opening edge of the notch 301 having the semicircular shape in plan view formed in the distal end edge part of the electrode 300.

In the present modified example, a lower surface electrode 330 includes rolled copper foil 312 formed in a thickness similar to that of the embodiment described above, and the protrusion 331 with a thickness similar to that of the embodiment described above and a semicircular annular shape similar to that of the first modified example.

Since the protrusion 331 of this lower surface electrode 330 also has a sufficient thickness like the embodiment described above, the protrusion 331 functions as a stopper in the case of displacing a pulse heater H when the pulse heater H is heated and also a solder bond part is pressurized, and there is no fear that a void V of the inside of the solder bond part enlarges to cause insufficient bonding between an electrode of the other side and the electrode by solder.

In addition, the notch having the semicircular shape in plan view of each of the modified examples is formed by punching a through hole previously formed in a board in half by a pressing machine.

As described in the embodiment and the first and second modified examples described above, when the electrode of the flexible printed circuit board is soldered to a metal electrode made of the electrode formed in, for example, another printed circuit board or flexible printed circuit board by thermal pressurization, the lower surface electrode has more sufficient thickness than a lower surface electrode of a conventional flexible printed circuit board, and functions as the stopper of displacement of the pulse heater, with the result that a solder layer with a uniform thickness can he formed between the electrode of the flexible printed circuit board and the metal electrode.

By forming such a solder layer, the solder layer with high accuracy of thickness can be formed between each electrode of the comb-shaped electrode according to the embodiment and the electrode of the other side bonded to each this electrode, and even when a void is provided in solder interposed between both of these electrodes, the void is not crushed, with the result that both of the electrodes are fully bonded by the solder to improve the strength of a solder bond part.

Also, regardless of variations in solder thickness of the preliminary solder in a state before solder bonding between electrodes by the pulse heater, applied to the electrode, the solder layer with a constant thickness can be formed between each of the electrodes of the comb-shaped electrode and the electrode of the other side.

Even in the case of the comb-shaped electrode having the plural electrodes with different thicknesses, the solder layer with a constant thickness can similarly he formed between the comb-shaped electrode and the electrode of the other side by simultaneously heating and pressurizing the comb-shaped electrode by one pulse heater.

The solder bonding can be performed by an inexpensive pulse heater since it is unnecessary to perform displacement control of solder melt.

The thin solder layer according to thickness can be formed by setting the thickness of copper plating in 10 mm or less.

The flexible printed circuit board according to the present invention described above can suitably be used for cabling to the inside of electronic devices, such as a video camera or a digital camera having an autofocus function, the camera with electrical components or electronic components mounted at a high density, or a load measuring apparatus or a strain measuring device including a strain gauge for measuring a load or always measuring strain of a structural object over a long period of time, but the flexible printed circuit board is not necessarily limited to such use objects and can be used for portable computers, mobile telephones and various other electrical products, always carried by a user, to Which an unexpected shock such as a fall or an undesirable vibration is given during movement of, for example, walking, a train or an automobile by the user.

The dimensions, the shapes, the materials and the number of components of the flexible printed circuit board may not be limited to those described in the embodiment and each of the modified examples described above, and they may be properly be Changed within the scope capable of exerting action of the present invention.

For example, as the insulating layer, other insulating materials may be used instead of the polyimide layer. Also, the number of electrodes forming the comb-shaped electrode is not limited to three.

Also, the protrusion may be formed as the lower surface electrodes 130, 230, 330 as described in the embodiment and each of the modified examples, but unlike these, plated copper foil having a predetermined thickness may be applied partially around the through hole and thus the same advantageous can he archived. Specifically, a part of the annular plated copper foil which is applied around the through hole may be removed or may not be formed. Also, a protrusion which has a predetermined thickness and which does not electrically conduct to the lower surface electrode, that is, is electrically isolated from the lower surface electrode may be patterned.

What is claimed is:

1. A flexible printed circuit board comprising:
an insulating layer haying flexibility;
at least one electrode comprising:
an upper surface electrode formed on an upper surface of the insulating layer;
a lower surface electrode formed on a lower surface of the insulating layer; and
a through hole that penetrates the insulating layer and electrically connects the upper surface electrode and the lower surface electrode; and a protrusion formed at a position near the through hole.

2. The flexible printed circuit board according to claim 1,
wherein the upper surface electrode is formed by applying plated copper foil on the upper surface of the insulating layer at an entire portion configured as the electrode, and
Wherein the lower surface electrode is formed by partially applying plated copper foil at a peripheral edge portion of the through hole.

3. The flexible printed circuit board according to claim 1,
wherein the protrusion is configured by the lower surface electrode and is formed around a peripheral edge of the through hole to have an annular shape.

4. The flexible printed circuit board according to claim 1,
wherein more than two of the electrode are arranged in parallel with one another and to extend outward from a side edge of the insulating layer, and
wherein each of the electrode is configured to be provided with the protrusion.
